(19) United States
(12) Patent Application Publication
(10) Pub. No.: US 2008/0248215 A1
(43) Pub. Date: Oct. 9, 2008

(54) DEVICE AND A PROCESS FOR DEPOSITING A METAL LAYER ON A PLASTIC SUBSTRATE

(75) Inventors: Peter Sauer, Schluechtern (DE); Hans-Georg Lotz, Gruendau-Rothenbergen (DE)

Correspondence Address: PATTERSON & SHERIDAN, L.L.P., 3040 POST OAK BOULEVARD, SUITE 1500, HOUSTON, TX, 77056, US

(73) Assignee: Applied Materials, Inc., Santa Clara, CA (US)

(21) Appl. No.: 12/027,370

(22) Filed: Feb. 7, 2008

Related U.S. Application Data
(60) Provisional application No. 60/910,081, filed on Apr. 4, 2007.

(30) Foreign Application Priority Data
Apr. 4, 2007 (EP) 07 007 108.9

(51) Int. Cl. B08B 6/00; H05H 1/00; B05C 9/08; C23C 14/34

(52) U.S. Cl. 427/534; 134/1.1; 118/620; 204/192.1; 204/298.02

(57) ABSTRACT

The invention relates to a process and to a web deposition machine for coating a plastic substrate with at least one metal layer, in particular plastic foil for flexible, printed circuit boards, wherein before depositing a first layer onto a surface of the plastic substrate to be deposited, a non depositing pretreatment of this surface is performed. It is the object of the invention to provide a process as described above through which the adhesion of metal layers on a plastic substrate is improved. Furthermore, a web deposition machine shall be provided through which such process can be performed. The object is accomplished through a process so that the non depositing pretreatment is performed in two steps, thus in a first step in which the surface of the plastic substrate (2) is cleaned with a non reactive low energy plasma (14), and in a second step in which the surface of the plastic substrate (2) is activated through reactive high energy ion radiation (17).

### CROSS-REFERENCE TO RELATED APPLICATIONS

This application claims priority to U.S. Provisional Patent Application Ser. No. 60/910,081, filed Apr. 4, 2007, entitled “A Device and a Process for Depositing a Plastic Substrate,” which is incorporated herein in its entirety by reference.

### BACKGROUND OF THE INVENTION

1. Field of the Invention

Embodiments of the invention generally relate to a process for depositing at least one metal layer on a plastic substrate, in particular plastic foil for flexible, printed circuit boards, wherein a non depositing preparation of a surface is performed before depositing a first layer onto a surface of the plastic substrate that is to be deposited.

2. Description of the Related Art

The invention furthermore relates to a web deposition machine for depositing at least one metal layer on a plastic foil web, in particular for flexible, printed circuit boards, wherein a pretreatment unit for a non depositing pretreatment of a surface of the plastic foil web is provided, which is located in front of a first deposition section in the transport direction of the plastic foil web through the web deposition machine.

The said process and device are being used for depositing plastics with mostly plural metal layers, preferably through sputtering. Plastic substrates metallized in this manner, are among other things, plastic foil base materials for the manufacture of flexible, printed circuit boards, as they are being used in monitors, cameras, mobile phones, etc. A major application is also print cartridges of printers, in which substantial flexible circuit boards paths are required as circuit surfaces.

Next to requirements with respect to a high mechanical resiliency, these applications also have stringent requirements with respect to temperature stability. Thus the metallic topographies deposited onto the plastic foils have to be solder able, so that short term temperatures of up to 400° can occur. Being used in electronic components in mobile technology, as e.g. in cars and aircraft, the circuit boards are furthermore exposed to climatic impacts as moisture precipitation, and considerable alternating loads through temperature changes. Permanent mechanical and thermal alternating loads induce such structural tensions in the layer system, which cause premature delamination of the layer material, in case of insufficient adhesion of the metallic layers on the surface of the plastic foil, thereby degrading the quality properties of the deposited plastic foil in an undesirable manner.

For improving the adhesion of the metal layers deposited onto the plastic substrate, it is known to pre treat the surface with plasma before the actual deposition process. The plasma is generated through ionization of a gas or gas mix, wherein positively charged gas ions and free electrons are created under energy induction. Then the plasma is brought into direct contact with the surface of the plastic substrate. During this plasma treatment, contaminations and minimal moisture films are removed from the surface of the plastic substrate. However, the surface roughness is hereby generally also increased.

A non depositing pretreatment according to the invention means a pretreatment, in which substantially no layer material is deposited onto the surface of the plastic substrate. It certainly cannot be excluded for process and manufacturing reasons that single alien atoms, also metal atoms, which may be present in the plasma can reach the surface of the plastic substrate to be treated and deposited thereupon. This however is not a deposition of the surface.

In the Patent document CH 682821A5 a process for treating a substrate surface, in particular plastic foils for packaging, is described before depositing a permeation barrier from non organic material, during which the substrate surface is exposed to plasma impact. The plasma is generated in a first variant with a high frequency hollow anode and an electrode connected to ground potential, in this case the plastic foil, wherein the hollow anode extends along the whole width of the foil web. A bias voltage is formed on the substrate surface, through which the ions of the plasma gas are further accelerated in the direction of the substrate surface. The power per surface area is approximately 3 W/cm² according to a preferred embodiment. In a second variant, the plasma is generated with magnetron cathodes with the same geometric extension. The magnetron cathodes can be provided with a magnetic field, weakened at inside pole, through which the plasma density at the substrate is increased. The magnetron cathodes are supplied with high frequency AC voltage or DC voltage. The energy rich ions of the plasma, which come in contact with the substrate surface, cause a cleaning and simultaneously a chemical excitation and activation of the surface, through which a better compound adhesion of the permeation blocker is achieved on the plastic foil, also during high transport speed of the substrate through the vacuum chamber.

The Patent document EP 0 386 459 A1 describes a process for manufacturing thin layer circuits on a substrate with a non conductive surface, in which the surface of the substrate is pre cleaned through plasma treatment before sputtering on a base metallization, which generates adhesion. In a preferred embodiment, a ceramic substrate is covered with a polyimide layer, forming the non conductive surface. The surface is initially washed thoroughly and degreased and subsequently exposed to argon plasma in a vacuum system. During the plasma treatment, which is also called sputter etching, contaminations, which still adhere to the surface after washing and degreasing, are being removed, and the surface of the polyimide layer is roughened, before the base metallization from CuCr or NiV with a thickness of 0.2-1 μm is sputtered on. Thus, the sputter etching according to the embodiment should last for about 5 minutes. As a result, a well adhering metallization on polyimide layers or polyimide substrates is accomplished, wherein the often used copper polyimide compound shows an adhesion of up to 1.5 N/mm in a peel test.

The patent document U.S. Pat. No. 5,484,517 describes a process for generating a multi element thin layer sensor on a polyimide foil. The manufacture of the multi element thin layer sensor comprises several cleaning steps. Initially the surface of the polyimide foil is cleaned multiple times through ultrasound in a hot solution of deionized water and cleaner with at least 180° F. and rinsed with deionized water at room temperature. After drying in an oven at approximately 350° F., the foil is cleaned in a vacuum chamber under continuous ion beam bombardment through argon ions, while nickel is simultaneously vaporized onto the surface. In a preferred embodiment, both processes run simultaneously, until the nickel layer has a thickness of e.g. 200 Ångström. Thereafter, the ion beam cleaning with argon gas is interrupted and the nickel vapor deposition is continued until the nickel layer has reached a thickness of approximately 2500 Ångström. This is ion beam assisted deposition (IBAD), in which the substrate is additionally treated with an ion beam during the deposition process. This causes an improved adhesion of the nickel layer to be deposited, and a reduced tension and more strength in the deposited layer. Since the ion bombardment primarily supports a deposition process here, the treatment method does not relate to a non depositing pretreatment of the plastic substrate according to the invention, so that the previously described EP 0 386 459 A1 can very well be considered as the most pertinent state of the art.

In the application of the metallized plastic substrates, in particular as flexible circuit boards, it has become apparent that the known methods for the pretreatment of the plastic substrate are not suitable to assure the adhesion of the deposited metal layers in a sufficient manner.

Thus it is the object of the invention to provide a process as described above, through which the adhesion of metal layers on a plastic substrate is improved. Furthermore, a web deposition machine shall be provided, through which such process can be implemented.

### SUMMARY OF THE INVENTION

The object is accomplished through a process with the features of patent claim 1. The present invention provides a process for treating a plastic substrate that includes cleaning a surface of the plastic substrate with a non-reactive low energy plasma and activating the surface of the plastic substrate with a reactive high energy ion radiation. The measures described in the dependent claims 2 to 15 describe preferred embodiments of the process according to the invention.

The object is furthermore accomplished through a process with the features of patent claim 16. The present invention furthermore provides a process for treating a plastic substrate that includes cleaning a surface of the plastic substrate with a non-reactive low energy plasma and activating the surface of the plastic substrate with a reactive high energy ion radiation. Additionally the process includes depositing an adhesion enhancement layer onto the surface of the plastic and depositing a metal layer onto the surface of the adhesion enhancement layer. The measures described in the dependent claims 17 to 22 describe preferred embodiments of the process according to the invention.

The object is furthermore accomplished through a web deposition machine according to the features of Patent claim 22. The present invention furthermore provides an apparatus for coating a plastic foil web including a pretreatment unit placed before a deposition section along a process direction. The pretreatment unit includes a first treatment section that cleans the plastic foil web with a non-reactive low energy plasma and a second treatment section that activates the surface of the plastic foil web with a reactive high energy ion radiation. Advantageous embodiments of the web deposition machine according to the invention can be derived from the dependent claims 23 to 25.

### BRIEF DESCRIPTION OF THE DRAWINGS

So that the manner in which the above recited features of the present invention can be understood in detail, a more particular description of embodiments of the invention, briefly summarized above, may be had by reference to embodiments, some of which are illustrated in the appended drawing. It is to be noted, however, that the appended drawing illustrates only typical embodiments of this invention and are therefore not to be considered limiting of its scope, for the invention may admit to other equally effective embodiments.

FIG. 1 shows a view of the major elements of a web depositing machine according to an embodiment of the present invention.

### DETAILED DESCRIPTION

According to the invention, the non-depositing pretreatment of the plastic substrate is performed in two steps. Thus in a first step, the surface of the plastic substrate is being cleaned with a non-reactive low energy plasma, and in a second step, the surface of the plastic substrate is activated through a reactive, high-energy ion radiation.

Surprisingly it has become evident, that through the step by step pretreatment of the plastic substrate according to the invention, in the sequence and combination of the claimed process parameters, an adhesion of the metal layers on the plastic substrate, in particular on plastic foils, can be accomplished up to the tear strength of the plastic.

According to the known state of the art it had to be assumed with reference to plasma pretreatment that a further pretreatment of the surface after a plasma treatment did not appear to be useful, since no further advantages beyond the cleaning and roughing effect known so far, were to be expected. It rather had to be assumed that the pre cleaning or surface structure reached with the plasma treatment would rather be disturbed in a non desirable manner through additional pre treatment measures.

However, the plasma used according to the invention in the first pre cleaning step is composed energetically and chemically, so that the plasma treatment alone may be performed to remove possible contaminations and moisture on the plastic substrate. A surface treatment, in which the surface is roughened, is explicitly not intended in the first pretreatment step, and thus avoided. Through the plasma application, interactions between the particles of the plasma and those of the plastic substrate occur on the surface or areas close to the surface. Depending on the choice of the process parameters (type of plasma generation, voltage, current, type and pressure of the process gas), these interactions can cause either a removal of particles (e.g. H₂O) adsorbed on the substrate surface, an excitation of surface atoms, the breaking of connections on the surface, or a modification of the substrate surface through chemical reactions. With process parameters, which cause the low energy, non reactive plasma provided by the invention, it can be adjusted that preferably only the removal of particles adsorbed on the surface preferably occurs. For realizing the non reactive plasma, a noble gas, preferably argon is used as a process gas.

A particularly low energy plasma pretreatment, in which the plastic substrate is only gently treated in an advantageous manner, and the surface structure is not broken open or roughened, achieves low energy plasma with a particularly low power density, preferably in a range of 0.05 to 1 W/cm².

Plasma is preferably ignited through glow discharge, which can be maintained by a DC power source as well as an AC power source, wherein the glow discharge can be operated with a low voltage potential of 0.1 kV to 1 kV.

Not until the second pretreatment step is the surface of the plastic substrate activated through a reactive high energy ion radiation of this surface. Hereby, an intended removal of surface atoms is performed under intense and oriented ion bombardment. The invention hereby assumes that the manner and the magnitude of the removal largely depend on the ion energy, which is generated by the ion mass and its acceleration on the surface. The ion radiation according to the invention therefore has high power density, in particular a power density in the range of 1 to 10 W/cm², preferably 1 to 5 W/cm², in particular 1 to 3 W/cm².

The ion radiation is provided through an ion source, in which positively charged ions are generated through an electric gas discharge, preferably with argon as operating gas, which subsequently incur an additional electrical acceleration and which are directed towards the plastic substrate with a high impulse. The ion source is therefore preferably operated with a high voltage potential of 1 kV to 3 kV. The high energy ions hit the surface of the plastic substrate with high energy or penetrate into the surface structure, wherein they deliver their kinetic energy to the surface structure. Thus interactions with the atoms on the surface of the plastic substrate occur, which, under high energy input through the ions, not only lead to an excitation and ionization of these solid body atoms, but also to a defect and void creation in the surface structure, and to a removal (sputtering) of atoms from the surface, also called ion induced surface sputtering. This way the surface is not only intensively roughened for the subsequent deposition processes, but also an activation energy for the subsequent chemical reactions with the layering material is provided, so that an improved layer adhesion of the layer to be deposited is assured.

In connection with a reactive atmosphere of the ion radiation according to the invention, in which reactive gases, preferably oxygen and/or nitrogen, are inducted into the ion beam, reactive gas atoms and gas ions hit the surface structure simultaneously and are adsorbed by it, wherein the reactive gas molecules are imbedded into the surface structure, so that the subsequent chemical reaction of the plastic substrate with the layer material to be deposited is facilitated in particular.

As a result, the layer adhesion of the subsequently deposited layer material becomes so good, that in an adhesion test of the compound foil manufactured in this manner, no delamination of the layers occurs through a peel test, but the compound material itself tears previously. Furthermore, a previously occurring weakening of the adhesion under cyclical climate variations, as simulated in climate tests, is successfully counteracted, so that an improved resistance of the composite material against external influences can be inferred.

The power density of the ion beam on the surface of the plastic substrate is increased, when the ion source generates a band shaped ion beam, which is focused, so that the ion beam hits the surface of the plastic substrate in a line. The focusing is accomplished in particular in the context with a preferred voltage potential of the ion source of at least 1 kV. In a motion of the plastic substrate relative to the ion beam thus provided, the surface of the plastic substrate can be radiated therewith constantly and intensely. For a continuous radiation of the plastic substrate, the linear projection of the focused ion beam is performed preferably perpendicular to a transport direction of the plastic substrate.

In a preferred embodiment, a polyimide foil is used as plastic substrate, since it is particularly robust against mechanical and thermal loads, which naturally also has positive effects on the adhesion of the metal layers in the final compound foil state. Therefore, polyimide foil is preferably used for flexible circuit boards and conductive paths.

The foil preferably has a foil thickness in a range of 12.5 μm to 50 μm, since in this range the required foil properties, like e.g. a high tear resistance, bear an economically favorable relationship to the considerable materials cost of the plastic material.

The process according to the invention is used favorably in particular for the pretreatment of plastic foils, onto which subsequent layers are deposited through sputtering. In a preferred embodiment, an adhesion layer is deposited in a first deposition step through sputtering, wherein preferably chromium (Cr), nickel (Ni), nickel chromium (NiCr), or chromium titanium (CrTi) with a layer thickness of preferably 2 nm to 40 nm is formed as a layer material. Subsequently preferably a metal layer preferably from copper or a copper alloy is sputtered on, wherein the layer thickness is provided preferably in a range of 150 μm to 300 μm.

According to the invention, a web deposition machine is additionally proposed, in which the pretreatment unit is provided with a first treatment section for cleaning the surface of the plastic foil web with a non reactive low energy plasma, and a second treatment station following in transport direction for activating the surface of the plastic foil web with a reactive high energy ion beam. With this web deposition machine, the process according to the invention using plastic foil webs can be performed in-line with the previously described advantages.

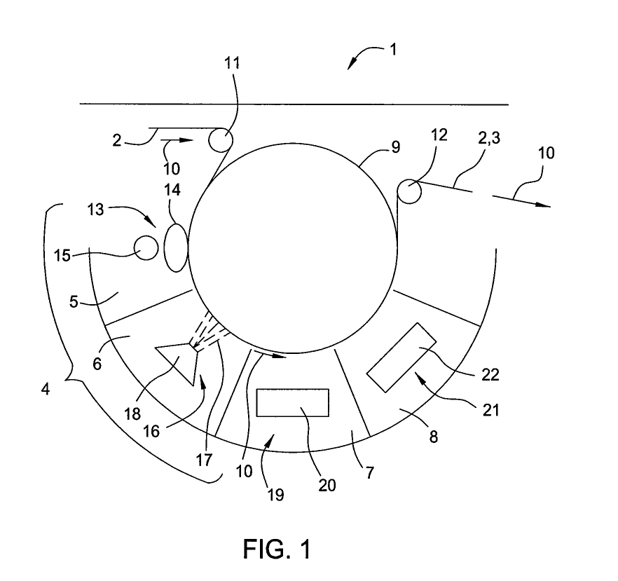

Further features and advantages of the invention, in particular of the web deposition machine according to the invention, can be derived from the subsequent description of a preferred embodiment and the appended drawing in FIG. 1.

FIG. 1 shows the major elements of a web depositing machine 1 according to the embodiment for depositing metal layers onto a plastic foil web 2 in a schematic view. The composite foil 3 to be manufactured by the web depositing machine 1 is used in particular as a base product for flexible, printed circuit boards. The web deposition machine 1 has a pretreatment unit 4 for a non depositing pretreatment of the plastic foil web 2, comprising a first treatment station 5 and a second treatment station 6. The web depositing machine 1 furthermore has a first and a second deposition section 7, 8 for depositing onto the plastic foil web 2, wherein the said sections 5, 6, 7, 8 are subsequently arranged around a central deposition roller 9, which serves as a substrate carrier. The plastic foil web 2, e.g. from polyimide foil 2, with a thickness of 38 μm is run from a winder, which is not shown, via lateral expansion and pull rollers, which are also not shown, into the direction of the arrow 10, which indicates the transport direction 10 of the plastic foil web 2, via a first pulley roller 11, onto a deposition roller 9. The plastic foil web 2 is run after the evacuation of the sections 5, 6, 7, 8 of the foil deposition machine 1 along the circumference of the deposition roller 9 with a velocity of 1.3 m/min, initially through the pretreatment unit 4, and subsequently through the first and second deposition section 7, 8, and subsequently leaves the web deposition machine 1 via a second pulley roller 12 towards an additional winder, which is not shown.

In the first treatment section 5, a glow discharge device 13 for cleaning the surface of the polyimide foil 2 with plasma 14 is located. The glow discharge device 13 is therefore provided with a magnetron and a glow cathode 15, e.g. made from stainless steel, titanium or molybdenum. The glow discharge device 13 is operated with a low voltage potential of 0.5 kV with a current of 0.3 A, so that a low energy plasma 14 with a power density of 0.15 W/cm² is created. The glow discharge device 13 is thereby disposed so that the generated plasma 14 is in direct contact with the polyimide foil 2. As a process gas for generating the non reactive plasma 14, argon with a gas volume flow of 200 sccm (standard cm³/min), corresponding to the power density is being used, wherein the gas pressure in the treatment station 5 is approximately 2×10⁻² mbar. Thereby, the set power density of the plasma 14 is adjusted to the predetermined web velocity of the foil throughput, which is mostly determined by the deposition processes in the subsequent deposition sections 7, 8. If a lower web velocity is being run, the power density has to be set lower, on the other hand in case of a higher web velocity, e.g. 1.8 m/min, the power density can be in an upper range of 0.2 W/cm² correspondingly.

In the second treatment section 6, a linear ion source 16 for generating an ion beam 17 is installed, wherein the linear ion source 16, into which a plasma generator 18 with a longitudinally extending magnetron is integrated, extends perpendicular to the drawing plane, so that the linear ion source 16 is disposed perpendicular to the transportation direction 10 of the plastic foil web 2. The argon process gas inducted into the plasma generator 18 is ionized, accelerated, and formed into a high energy ion beam 17, which is directed onto the surface of the polyimide foil 2. Through the impact of the ions, the surface is activated through the energy influx. For the generation of a high energy ion beam, the plasma generator 18 is operated with a voltage potential of 3 kV at a current of up to 3.0 A, wherein the gas volume flow of the argon process gas in the ion source is set to 16 to 20 sccm. Oxygen with a gas volume flow of 200 sccm and a nitrogen with a gas volume flow of 20 sccm are inducted into the ion beam 17, in order to create a suitable reactive atmosphere in the treatment station 6, wherein an oxygen gas pressure of 3×10⁻³ mbar is set in the treatment section 6.

In the pretreatment unit 4, the polyimide foil 2 is thus initially exposed to low energy, non reactive plasma 14, and subsequently bombarded with a high energy ion beam 17, wherein no depositing processes take place.

In the first deposition section 7 following the pretreatment unit 4, a sputter assembly 19 with a magnetron is disposed, which has a cathode 20 with e.g. a NiCr-target, through which a first layer, thus an adhesion enhancement layer from nickel chromium (NiCr) is sputtered onto the polyimide foil 2, previously pretreated in the pretreatment unit 4. Thereby the cathode power is 2 kW. The adhesion enhancement layer is deposited onto the polyimide foil 2 with a thickness of 10 μm. This adhesion enhancement layer also serves as an etching substance besides the adhesion enhancement between the polyimide foil 2 and the subsequent layer, in order to support the etching process for manufacturing circuit structures on the polyimide foil 2, which occurs outside of the web deposition machine 1.

In the second deposition section 8 following in transport direction 10, an additional sputter device 21 with a magnetron is disposed, whose cathode 22 e.g. has a Cu target. Through this sputter assembly 21, a copper (Cu) layer with a layer thickness of 150 nm is sputtered onto the adhesion enhancement layer as a subsequent layer with a cathode power of 20 kW.

The sputter processes in the two deposition sections 7, 8 each occur under an argon atmosphere with a gas flow of 150 sccm and a gas pressure of 3×10⁻³ mbar.

For the completion of the composite foil 3, a further deposition mostly occurs outside the web deposition machine 1, e.g. through galvanizing (electroplated), wherein e.g. copper is deposited once more with a layer thickness of 24 μm. Then the circuit structures are etched subsequently.

With the process technique combination of the previously described pretreatment measures, realized in the previously described web deposition machine 1, particularly well adhering copper-polyimide-composite foils 3 are achieved under the selected process parameters, which reach an adhesion of up to 14.1 N/cm in a peel strength test. The invention, however, is not limited at all to the layer materials described, but it is also applicable to the adhesion improvement of other layer sequences.

While the foregoing is directed to embodiments of the invention, other and further embodiments of the invention may be devised without departing from the basic scope thereof, and the scope thereof is determined by the claims that follow.

What is claimed is:

1. A process for treating a plastic substrate, comprising:
cleaning a surface of the plastic substrate with a non-reactive low energy plasma; and
activating the surface of the plastic substrate with a reactive high energy ion radiation.

2. The process of claim 1 wherein the non-reactive low energy plasma has a power density from about 0.05 W/cm² to about 1 W/cm².

3. The process of claim 1 wherein the non-reactive low energy plasma comprises an ionized noble gas.

4. The process of claim 3 wherein the ionized noble gas comprises argon.

5. The process of claim 1 wherein the non-reactive low energy plasma is generated by a glow discharge device operating at a voltage potential from about 0.1 kV to about 1 kV.

6. The process of claim 1 wherein the power density is from about 1 W/cm² to about 5 W/cm².

7. The process of claim 5 wherein the power density is from about 1 W/cm² to about 3 W/cm².

8. The process of claim 1 wherein the reactive high energy ion radiation is generated by an ion source operating at a voltage potential greater than 1 kV.

9. The process of claim 8 wherein the ion source operates at a voltage potential from about 1 kV to about 3 kV.

10. The process of claim 8 wherein the ion source comprises argon.

11. The process of claim 1 wherein a reactive atmosphere of the reactive high energy ion radiation is generated through induction of a reactive gas comprising oxygen or nitrogen.

12. The process of claim 1 wherein the reactive high energy ion radiation generates a band shaped ion beam that hits the surface of the plastic substrate in a line.

13. The process of claim 12 wherein the ion beam is projected onto the surface of the plastic substrate perpendicular to a transport direction of the plastic substrate.

14. The process of claim 1 wherein the plastic substrate comprises a foil chosen from the group consisting of polyesters, polyethylenes, polypropylenes, polyamides, and polyimides.

15. The process of claim 14 wherein the foil has a thickness from about 12.5 μm to about 50 μm.

16. A process for treating a plastic substrate, comprising:
cleaning a surface of the plastic substrate with a non-reactive low energy plasma;
activating the surface of the plastic substrate with a reactive high energy ion radiation;
depositing an adhesion enhancement layer onto the surface of the plastic; and,
depositing a metal layer onto the surface of the adhesion enhancement layer.

17. The process of claim 16 wherein the adhesion enhancement layer comprises at least one of chromium (Cr), nickel (Ni), nickel chromium (NiCr), and chromium titanium (CrTi).

18. The process of claim 16 wherein the adhesion enhancement layer thickness is from about 2 nm to about 40 nm.

19. The process of claim 16 wherein the metal layer comprises copper or a copper alloy.

20. The process of claim 16 wherein the metal layer thickness is in the range of about 150 μm to about 300 μm.

21. The process of claim 16 wherein at least one of the depositing an adhesion enhancement layer and the depositing a metal layer is accomplished by a sputtering process.

22. An apparatus for coating a plastic foil web, comprising:
a pretreatment unit placed before a deposition section along a process direction, the pretreatment unit comprising:
a first treatment section that cleans the plastic foil web with a non-reactive low energy plasma;
a second treatment section that activates the surface of the plastic foil web with a reactive high energy ion radiation.

23. The apparatus of claim 22 wherein the first treatment section comprises a magnetron with a glow cathode.

24. The apparatus of claim 23 wherein the second treatment section comprises a plasma generator with a magnetron.

25. The apparatus of claim 24 wherein the deposition section comprises a first sputter assembly and a second sputter assembly.
